(19) United States
(12) Patent Application Publication
(10) Pub. No.: US 2026/0181809 A1
(43) Pub. Date: Jun. 25, 2026

(54) SERVERS AND SERVER CHASSIS THEREOF

(71) Applicant: Giga Computing Technology Co., Ltd., New Taipei City (TW)

(72) Inventors: Chia-Chen Lu, New Taipei City (TW); Ching-Chuan Huang, New Taipei City (TW)

(73) Assignee: Giga Computing Technology Co., Ltd., New Taipei City (TW)

(21) Appl. No.: 19/399,088

(22) Filed: Nov. 24, 2025

(30) Foreign Application Priority Data
Dec. 20, 2024 (TW) 113150057

(51) Int. Cl. H05K 7/14; H05K 7/20

(52) U.S. Cl. CPC H05K 7/1487; H05K 7/20727

(57) ABSTRACT

A server includes a motherboard, a connecting cable and a server chassis. The server chassis includes a chassis body, two guiding plates and an expansion device. The two guiding plates are respectively fixed on a base board of the chassis body and are spaced apart from each other. Each guiding plate has two assembling parts spaced apart from each other. Each assembling part includes a guiding groove and a first positioning groove. Two side surfaces of the expansion device have two guiding posts spaced apart from each other. These guiding posts enter the guiding groove along an extension direction and are fixed to the first positioning groove along the assembling direction, so that the expansion device is fixed in an assembling space. The motherboard is fixed on the base board and has connectors. Two ends of the connecting cable are electrically connected to the connector and the expansion device.

### CROSS-REFERENCE TO RELATED APPLICATION

This non-provisional application claims priority under 35 U.S.C. § 119(a) to Patent Application No. 113150057 filed in Taiwan, R.O.C. on Dec. 20, 2024, the entire contents of which are hereby incorporated by reference.

### BACKGROUND

### Technical Field

The disclosure relates to a server and a server chassis thereof, and in particular to, a server that uses guiding plates to assist in assembling expansion devices, and a server chassis thereof.

### Related Art

Currently, when an expansion kit (storage circuit or computing circuit) is to be installed to a server, the expansion kit is assembled into a server chassis through slide rails of the chassis. The expansion kit needs to be electrically connected to a connector of a motherboard through a connecting cable. Therefore, operators need to reserve a large length of connecting cable. Otherwise, if the connecting cable is too short, the expansion kit needs be removed from the server chassis for connecting cable replacement. In addition, a plurality of connecting cables are often bundled together, so that when the expansion kit is inserted into the chassis through the slide rails, the connecting cables will obstruct the expansion kit from sliding. Moreover, excessive connecting cables will occupy significant heat dissipation space, resulting in poor heat dissipation of the server chassis for the expansion kit.

### SUMMARY

In view of this, in some embodiments, a server includes a server chassis, a motherboard and a connecting cable. The server chassis includes a chassis body, two guiding plates and an expansion device. The chassis body includes a base board. The two guiding plates are respectively fixed on the base board and are spaced apart from each other. An assembling space is provided between the two guiding plates and the base board. Each of the guiding plates has a long side, a short side and two assembling parts. The two assembling parts are spaced apart from each other. Each assembling part includes a guiding groove and a first positioning groove. An extension direction of the guiding groove is parallel to the short side. The first positioning groove is in communication with the guiding groove and has an assembling direction. The assembling direction is not perpendicular to the long side. The expansion device has two side surfaces. The side surfaces have two guiding posts spaced apart from each other. The guiding posts respectively enter the guiding grooves of the assembling parts along the extension direction and are fixed to the first positioning grooves of the assembling parts along the assembling direction, so that the expansion device is fixed in the assembling space. The motherboard is fixed on the base board of the server chassis and has a connector. The expansion device has an air inlet surface and an air outlet surface in the assembling direction. The air inlet surface has a connecting part. The connecting part faces the motherboard. One end of the connecting cable is electrically connected to the connector. The other end of the connecting cable is connected to the connecting part.

In some embodiments, each of the guiding grooves includes an opening part and a bottom part. The bottom part is adjacent to the base board, and the first positioning groove is located between the opening part and the base board.

In some embodiments, each of the assembling parts further includes a second positioning groove. The first positioning groove is adjacent to the bottom part, and the second positioning groove is adjacent to the opening part.

In some embodiments, the first positioning groove and the second positioning groove of one of the guiding plates are symmetrical with the first positioning groove and the second positioning groove of the other of the two guiding plates in position in the extension direction.

In some embodiments, each of the guiding plates has the first positioning groove and the second positioning groove on one side surface, and a third positioning groove and a fourth positioning groove on the other side surface. The third positioning groove is adjacent to the bottom part, and the fourth positioning groove is adjacent to the opening part. The first positioning groove and the second positioning groove are offset from the third positioning groove and the fourth positioning groove in the extension direction.

In some embodiments, each of the guiding plates has the first positioning groove on one side surface and a third positioning groove on the other side surface. The first positioning groove is offset from the third positioning groove in the extension direction.

In some embodiments, the chassis body further includes a side plate connected to the base board. One of the guiding plates is fixed on the base board, and the other guiding plate is fixed on the side plate.

In some embodiments, a width of each of the guiding grooves is greater than twice a width of each of the guiding posts.

In some embodiments, each of the guiding plates has a limiting part, and the expansion device has a limiting member. When the guiding posts are respectively located in the first positioning grooves of the two guiding plates, the limiting member is matched with the limiting part.

In some embodiments, each of the guiding plates has a latch part, and the expansion device has a latching member. When the guiding posts are respectively located in the first positioning grooves of the two guiding plates, the latching member is matched with the latch part.

In some embodiments, the connecting cable has a first length, a distance between the air outlet surface and the connector is a second length, and a distance between the connecting part and the connector is a third length. The second length is greater than the third length, and the first length is between the second length and the third length.

In some embodiments, the expansion device has a heat dissipation space and an expansion circuit board. The heat dissipation space is in communication with the air inlet surface, the air outlet surface and the chassis body respectively, and the expansion circuit board is located in the heat dissipation space.

Based on the above, in the server in some embodiments, the two guiding plates are respectively fixed on the base board to form the assembling space. When the expansion device is to be assembled into the assembling space, the guiding grooves of the guiding plates can guide the guiding posts of the expansion device to move in the guiding grooves along the extension direction. When the guiding posts move to positions corresponding to the first positioning grooves, the guiding posts can be fixed in the first positioning grooves along the assembling direction, so that the expansion device is fixed in the assembling space. The expansion device is installed in the assembling space in the extension direction (i.e., the direction parallel to the short side). This can prevent the connecting cable connecting the expansion device to the connector from excessive length reserved, so that the expansion device is not blocked by the connecting cable and thus is prevented from affecting heat dissipation.

Various embodiments are described in detail below. However, the embodiments are provided merely as examples and do not limit the scope of protection of the disclosure. In addition, some components are omitted from the drawings in the embodiments to clearly illustrate the technical features of the disclosure. The same reference numerals in all drawings will be used to denote the same or similar components.

### BRIEF DESCRIPTION OF THE DRAWINGS

FIG. 1 is a three-dimensional view of a server in some embodiments of the disclosure;

FIG. 2 is an exploded view of a server in some embodiments of the disclosure, showing only a part of a motherboard provided with guiding plates;

FIG. 3 is a partial enlarged view of 3 in FIG. 1;

FIG. 4 is a top view of FIG. 1;

FIG. 5 is a schematic diagram (I) of an expansion device installed on a guiding plate in some embodiments of the disclosure;

FIG. 6 is a schematic diagram (II) of an expansion device installed on a guiding plate in some embodiments of the disclosure;

FIG. 7 is a front view of FIG. 1;

FIG. 8 is a schematic diagram of an implementation of a guiding plate in some embodiments of the disclosure;

FIG. 9 is a schematic diagram of an implementation of two guiding plates fixed on a base board in some embodiments of the disclosure;

FIG. 10 is a partial enlarged view of 10 in FIG. 1;

FIG. 11 is a schematic diagram (I) of operation of a latching member in FIG. 10; and

FIG. 12 is a schematic diagram (II) of operation of the latching member in FIG. 10.

### DETAILED DESCRIPTION

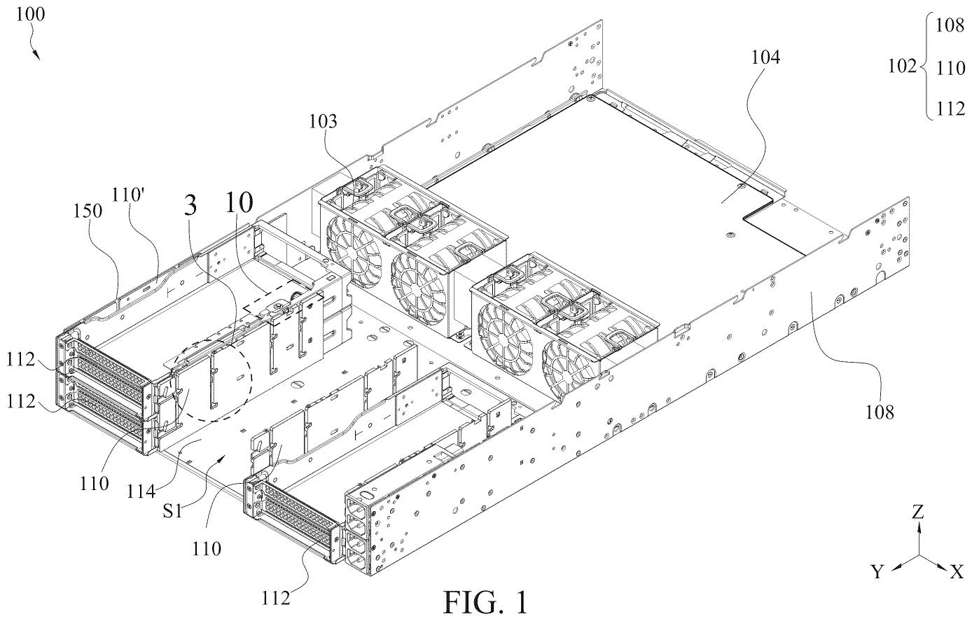

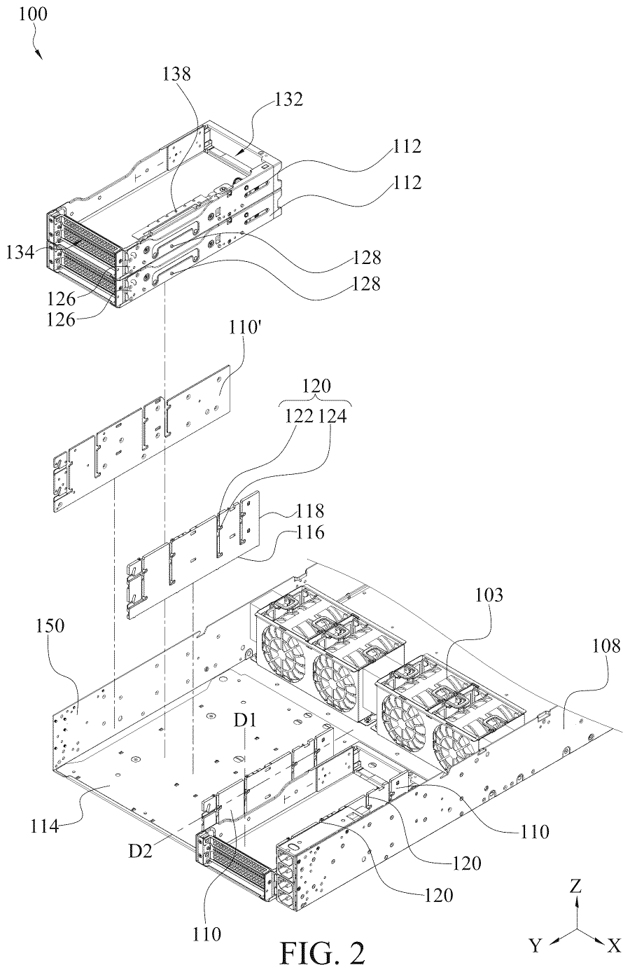

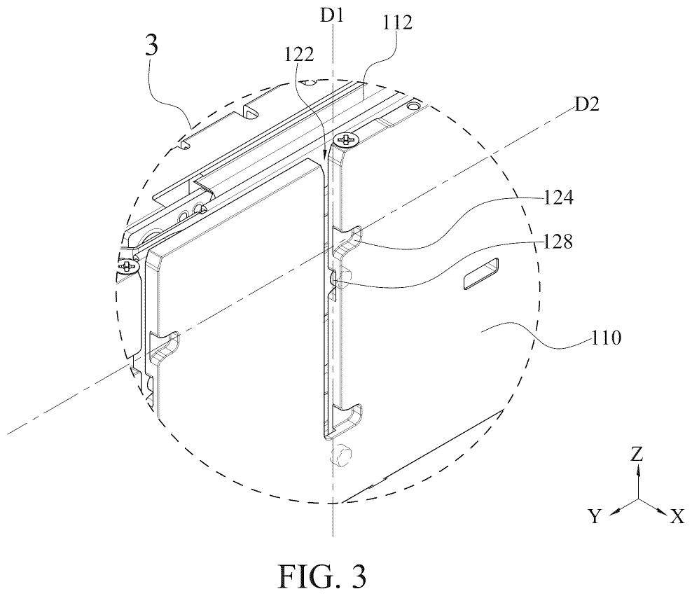

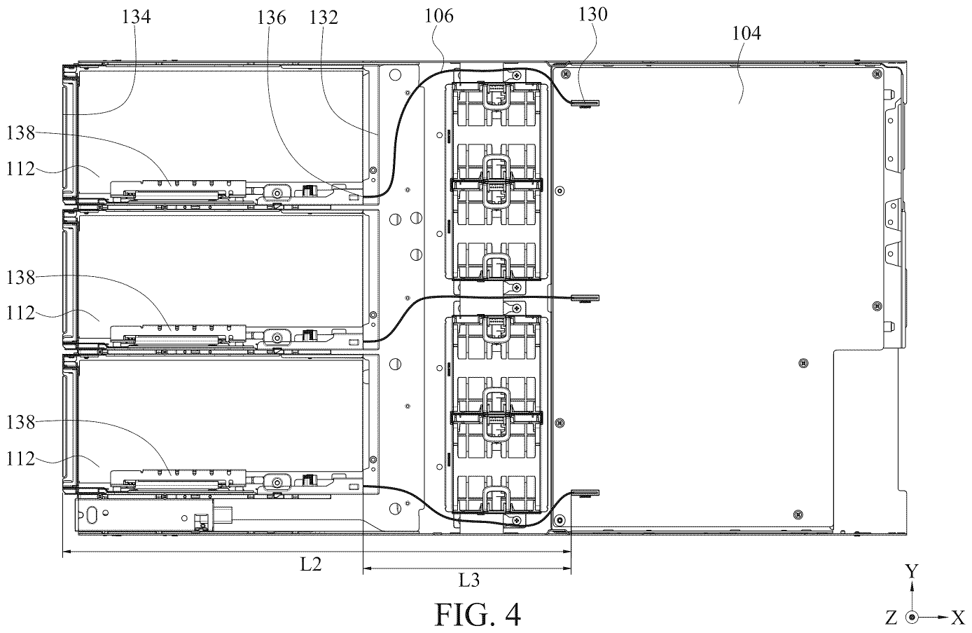

Referring to FIG. 1, FIG. 2 and FIG. 3, FIG. 1 is a three-dimensional view of a server in some embodiments of the disclosure. FIG. 2 is an exploded view of a server in some embodiments of the disclosure, showing only a part of a motherboard provided with guiding plates. FIG. 3 is a partial enlarged view of 3 in FIG. 1. In some embodiments, as shown in FIG. 1, FIG. 2 and FIG. 3, the server 100 includes a server chassis 102, a motherboard 104 and a connecting cable 106 (shown later in FIG. 4). The motherboard 104 and the connecting cable 106 are accommodated in the server chassis 102. The server 100 may be, for example, a GPU collaborative computing server, a rack server or a high-density storage server.

The server chassis 102 includes a chassis body 108, two guiding plates 110 and an expansion device 112. The chassis body 108 includes a base board 114. The two guiding plates 110 are respectively fixed on the base board 114 and are spaced apart from each other. An assembling space S1 is provided between the two guiding plates 110 and the base board 114. The two guiding plates 110 may be indirectly fixed on the base board 114 by locking, snapping, magnetic attraction, welding or the like, so that the guiding plates 110 can be arranged on the base board 114 and form the assembling space S1, allowing the expansion devices 112 to be assembled in the same assembling space S1. Herein, a size of the assembling space S1 may be set according to the dimensional specifications of the expansion device 112. The guiding plates 110 may also be directly locked to locking and fixing points of the base board 114. Any method enabling the guiding plates 110 to be arranged on the base board 114 can be implemented, without being limited to the foregoing description. In some embodiments, the chassis body 108 may include a removable cover. In FIG. 1, the removable cover is omitted for clarity to illustrate the relationship between the guiding plates 110 and the expansion device 112 inside the chassis body 108. The removable cover is assembled on an opposite side of the base board 114, so that the chassis body 108 forms an incompletely closed chassis.

Each guiding plate 110 has a long side 116, a short side 118 and two assembling parts 120. The two assembling parts 120 are spaced apart. Each assembling part 120 includes a guiding groove 122 and a first positioning groove 124. An extension direction D1 (Z-axis direction in FIG. 2) of the guiding groove 122 is parallel to a direction of the short side 118. The first positioning groove 124 is in communication with the guiding groove 122 and has an assembling direction D2. The assembling direction D2 is not perpendicular to a direction of the long side 116 (Y-axis direction in FIG. 2). For example, the assembling direction D2 of the first positioning groove 124 may be parallel to the direction of the long side 116 (as shown in FIG. 2, i.e., the assembling direction D2 is perpendicular to the extension direction D1), or the assembling direction D2 may form an included angle (this included angle ranges from 1° and 90°, such as 5° to 30°) with the long side 116. The expansion device 112 has two side surfaces 126. The side surfaces 126 have two guiding posts 128 spaced apart from each other.

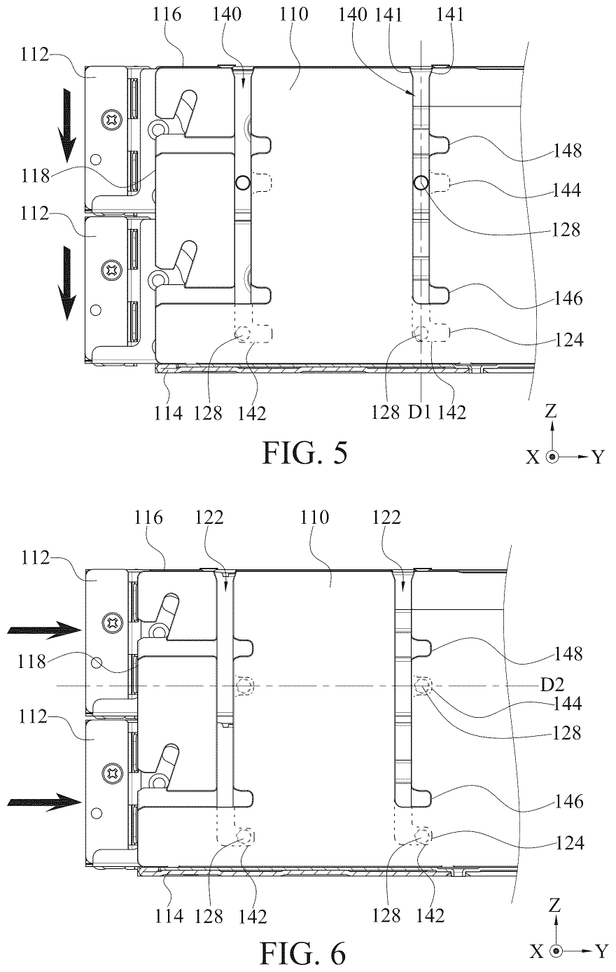

Referring to FIG. 2, FIG. 5 and FIG. 6, FIG. 5 is a schematic diagram (I) of an expansion device installed on a guiding plate in some embodiments of the disclosure. FIG. 6 is a schematic diagram (II) of an expansion device installed on a guiding plate in some embodiments of the disclosure. In some embodiments, as shown in FIG. 5 and FIG. 6, when installing the expansion device 112, these guiding posts 128 may respectively enter the guiding grooves 122 of the assembling parts 120 along the extension direction D1. When the guiding posts 128 and the first positioning grooves 124 are at the same height, the guiding posts 128 may be fixed in the first positioning grooves 124 of the assembling parts 120 along the assembling direction D2, so that the expansion device 112 is fixed in the assembling space S1. It should be noted that according to the length of the short side 118 (the length along the Z-axis direction in FIG. 2), one or more expansion devices 112 may be assembled in the assembling space S1. For example, FIG. 1 shows that one or two expansion devices 112 may be assembled in the same assembling space S1.

Referring to FIG. 2 and FIG. 4, FIG. 4 is a top view of FIG. 1. As shown in FIG. 2 and FIG. 4, the motherboard 104 is fixed on the base board 114 of the server chassis 102 and has a connector 130. The connector 130 may have an interface specification corresponding to the expansion device 112, such as PCIe, NVM Express or M.2.

The expansion device 112 may be a computing circuit or a storage circuit. The expansion device 112 has an air inlet surface 132 and an air outlet surface 134 in the assembling direction D2. The air inlet surface 132 has a connecting part 136. The connecting part 136 faces the motherboard 104. One end of the connecting cable 106 is electrically connected to the connector 130. The other end of the connecting cable 106 is connected to the connecting part 136. The connecting part 136 of the expansion device 112 is a terminal having a corresponding specification to the connector 130.

When the expansion device 112 is assembled in the chassis body 108, the expansion device 112 is assembled in the assembling space S1 along the extension direction D1 (the direction parallel to the short side 118). Here, the connecting cable 106 can establish an electrical connection between the connecting part 136 and the connector 130 without requiring excessive length reserved. This prevents excessive length reserved of the connecting cable 106 from lowering the heat dissipation effect in the server chassis 102.

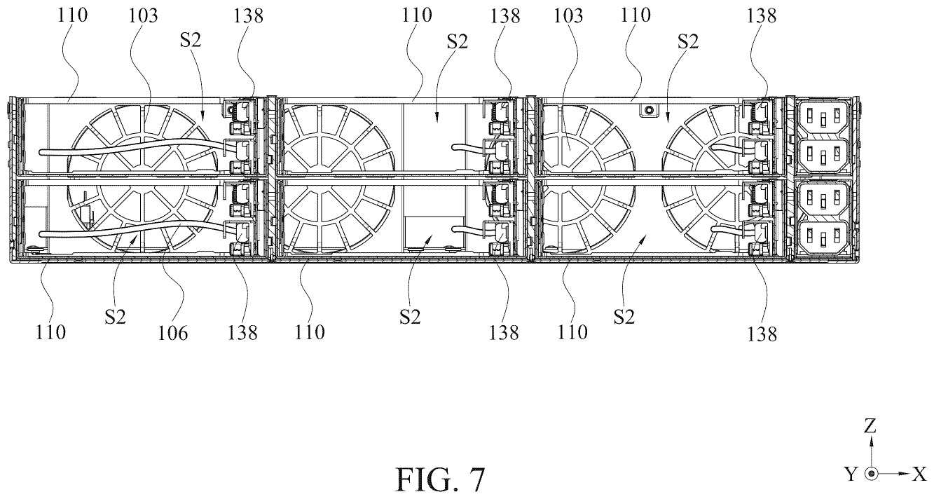

For example, referring to FIG. 4 and FIG. 7, FIG. 7 is a front view of FIG. 1. As shown in FIG. 7, the expansion device 112 has a heat dissipation space S2 and an expansion circuit board 138. The heat dissipation space S2 is in communication with the air inlet surface 132, the air outlet surface 134 and the chassis body 108 respectively, and the expansion circuit board 138 is located in the heat dissipation space S2. In some embodiments, the server 100 further includes at least one fan module 103. When activated, the fan module 103 may deliver airflow through the air inlet surface 132, the heat dissipation space S2 and the air outlet surface 134 sequentially to dissipate heat from the expansion circuit board 138 located in the heat dissipation space S2. It should be noted that since the connecting cable 106 does not require excessive length reserved, this can prevent the connecting cable 106 from obstructing too much airflow into the heat dissipation space S2, thereby ensuring the heat dissipation effect of the expansion device 112.

In some embodiments, as shown in FIG. 4, the connecting cable 106 has a first length (a length of each connecting cable 106 in FIG. 4). A distance between the air outlet surface 134 and the connector 130 is a second length L2. A distance between the connecting part 136 and the connector 130 is a third length L3. The second length L2 is greater than the third length L3, and the first length is between the second length L2 and the third length L3. Here, the existing server chassis realizes assembling through slide rails, and the connecting cable requires at least the second length L2 to connect smoothly to the connector. In contrast, the expansion device 112 is assembled in the assembling space S1 along the extension direction D1, and the connecting cable 106 requires only the first length to electrically connect to the connector 130.

In some embodiments, as shown in FIG. 2 and FIG. 5, each guiding groove 122 includes an opening part 140 and a bottom part 142. The bottom part 142 is adjacent to the base board 114. The first positioning groove 124 is located between the opening part 140 and the base board 114. The expansion device 112 may enter the guiding grooves 122 through the opening parts 140, so as to be assembled into the assembling space S1. In some embodiments, the opening part 140 includes two guiding slopes 141. A width of the guiding slope 141 is greater than a width of the guiding post 128. Thus, during the entry of the guiding posts 128 into the guiding grooves 122, the guiding slopes 141 can guide the entry of the guiding posts 128 into the guiding grooves 122.

In some embodiments, as shown in FIG. 2 and FIG. 5, each assembling part 120 further includes a second positioning groove 144. The first positioning groove 124 is adjacent to the bottom part 142, and the second positioning groove 144 is adjacent to the opening part 140. A distance between the first positioning groove 124 and the second positioning groove 144 may be determined according to a height of the expansion device 112 (a length of the expansion device 112 along the Z-axis direction in FIG. 5), so that two expansion devices 112 can be assembled in the same guiding groove 122.

In some embodiments, as shown in FIG. 2 and FIG. 5, the first positioning groove 124 and the second positioning groove 144 of one of the two guiding plates 110 are symmetrical with the first positioning groove 124 and the second positioning groove 144 of the other of the two guiding plates 110 in position in the extension direction D1. That is, the first positioning groove 124 and the second positioning groove 144 of the two opposite guiding plates 110 are at the same height in position (in the Z-axis direction in FIG. 5). Thus, when the guiding posts 128 respectively move in corresponding guiding grooves 122, the guiding posts can simultaneously enter the first positioning groove 124 and the second positioning groove 144.

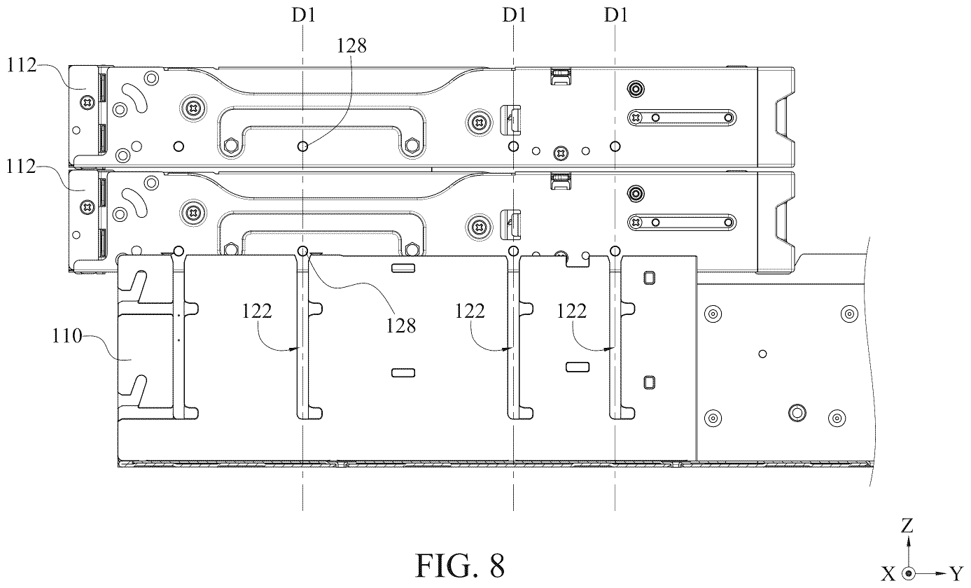

Referring to FIG. 8, FIG. 8 is a schematic diagram of an implementation of a guiding plate in some embodiments of the disclosure, in which the expansion device is assembled to the guiding plate. In some embodiments, as shown in FIG. 8, the guiding plate 110 has three guiding grooves 122. When the guiding posts 128 of the expansion device 112 respectively enter corresponding guiding grooves 122, the expansion device 112 can form three-point limiting with the two guiding plates 110 respectively on the two sides, so that the expansion device 112 can move stably relative to the two guiding plates 110.

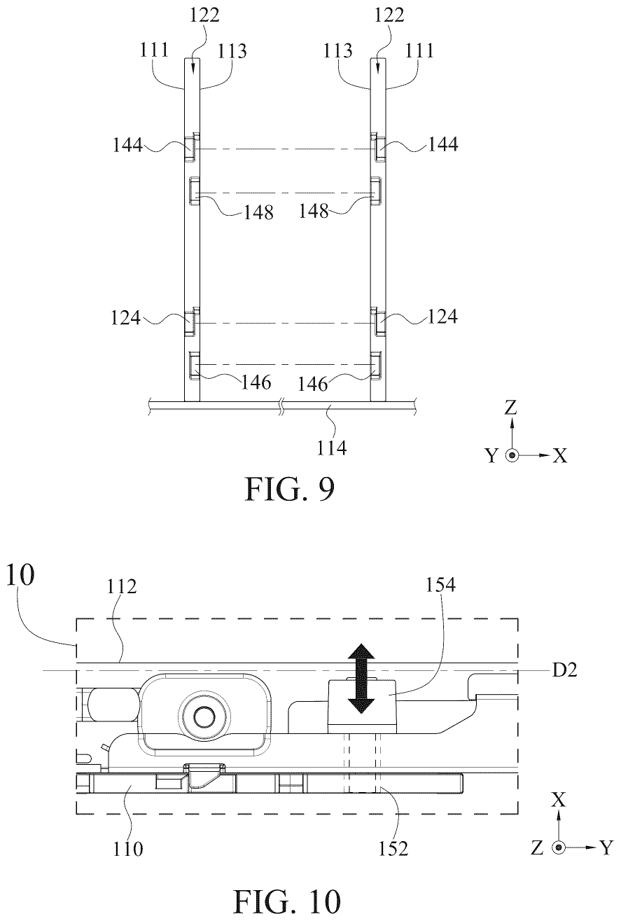

Referring to FIG. 2 and FIG. 9, FIG. 9 is a schematic diagram of an implementation of two guiding plates fixed on a base board in some embodiments of the disclosure. In some embodiments, as shown in FIG. 2 and FIG. 9, the first positioning groove 124 and the second positioning groove 144 of one of the two guiding plates 110 are symmetrical with the first positioning groove 124 and the second positioning groove 144 of the other of the two guiding plates 110 in position in the extension direction D1. That is, the two adjacent and opposite guiding plates 110 are arranged on the base board 114 in a mirrored configuration, such that the first positioning groove 124 and the second positioning groove 144 of the two guiding plates 110 are respectively at the same height in position (in the Z-axis direction in FIG. 9). Thus, when the guiding posts 128 respectively move in corresponding guiding grooves 122, the guiding posts can simultaneously enter the first positioning groove 124 and the second positioning groove 144.

As shown in FIG. 9, each guiding plate 110 has the first positioning groove 124 and the second positioning groove 144 on one side surface 111, and a third positioning groove 146 and a fourth positioning groove 148 on the other side surface 113. The third positioning groove 146 is adjacent to the bottom part 142, and the fourth positioning groove 148 is adjacent to the opening part 140. The first positioning groove 124 and the second positioning groove 144 are offset from the third positioning groove 146 and the fourth positioning groove 148 in the extension direction D1. The base board 114 may assemble two expansion devices 112 on two side surfaces (111, 113) of the same guiding plate 110 according to expansion requirements. The first positioning groove 124 is offset from the third positioning groove 146 in the extension direction D1, and the second positioning groove 144 is offset from the fourth positioning groove 148 in the extension direction D1. Thus, when the guiding post 128 of the expansion device 112 is fixed in the second positioning groove 144 and the guiding post 128 of the other expansion device 112 is fixed in the fourth positioning groove 148, since the second positioning groove 144 is offset from the fourth positioning groove 148, the guiding posts 128 of the expansion devices 112 can be assembled in the same guiding groove 122 without mutual interference. In some embodiments, the two side surfaces (111, 113) of the guiding plate 110 may only have one first positioning groove 124 and one third positioning groove 146 (or one second positioning groove 144 and one fourth positioning groove 148).

In some embodiments, a width of each of the guiding grooves 122 is greater than twice a width of each of the guiding posts 128. Thus, the guiding posts 128 of the two expansion devices 112 can be assembled simultaneously in the same guiding groove 122 without mutual interference.

In some embodiments, as shown in FIG. 2, the chassis body 108 further includes a side plate 150 connected to the base board 114. One guiding plate 110 may be fixed on the base board 114, and the other guiding plate 110′ may be fixed on the side plate 150. Thus, the assembling space S1 may also be formed between the guiding plate 110′ located on the side plate 150 and the guiding plate 110, so that the expansion device 112 can be assembled in this assembling space S1.

Referring to FIG. 10, FIG. 10 is a partial enlarged view of 10 in FIG. 1. In some embodiments, as shown in FIG. 10, each guiding plate 110 has a limiting part 152. The expansion device 112 has a limiting member 154. When the guiding posts 128 are located in the first positioning grooves 124 of the two guiding plates 110, the limiting member 154 is matched with the limiting part 152. The limiting part 152 may be a via, and the limiting member 154 may be an elastic pin. After the expansion device 112 is assembled in the assembling space S1, the elastic pin can be matched with the via. Thus, the elastic pin is located in the via, so that the elastic pin can provide a limiting effect on the expansion device 112 in the assembling direction D2.

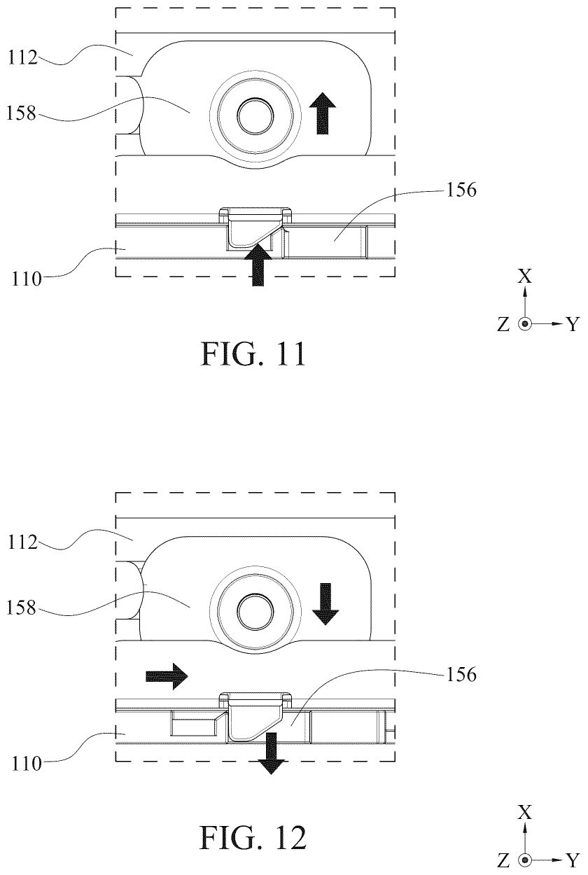

Referring to FIG. 11 and FIG. 12, FIG. 11 is a schematic diagram (I) of operation of a latching member in FIG. 10. FIG. 12 is a schematic diagram (II) of operation of the latching member in FIG. 10. In some embodiments, as shown in FIG. 11 and FIG. 12, each guiding plate 110 has a latch part 156. The expansion device 112 has a latching member 158. When the guiding posts 128 are respectively located in the first locating grooves 124 of the two guiding plates 110, the latching member 158 is matched with the latch part 156. The latch part 156 may be a recess, and the latching member 158 may be an elastic fastener. When the expansion device 112 moves in the guiding grooves 122, the elastic fastener may press against the guiding plate 110. When the expansion device 112 is fixed in the first positioning groove 124, the elastic fastener may be released and fixed in the recess, so that the elastic fastener can generate a limiting effect on the expansion device 112 in the assembling direction D2.

Based on the above, in the server 100 in some embodiments, the two guiding plates 110 are respectively fixed on the base board 114 to form the assembling space S1. When the expansion device 112 is to be assembled into the assembling space S1, the guiding grooves 122 of the guiding plates 110 can guide the guiding posts 128 of the expansion device 112 to move in the guiding grooves 122 along the extension direction D1. When the guiding posts 128 move to positions corresponding to the first positioning grooves 124, the guiding posts 128 can be fixed in the first positioning grooves 124 along the assembling direction D2, so that the expansion device 112 is fixed in the assembling space S1. The expansion device 112 is installed in the assembling space S1 in the extension direction D1. This can prevent the connecting cable 106 connecting the expansion device 112 to the connector 130 from excessive length reserved, so that the expansion device 112 is not blocked by the connecting cable 106 and thus is prevented from affecting heat dissipation.

What is claimed is:

1. A server chassis comprising:
a chassis body, comprising a base board;
two guiding plates, respectively fixed on the base board and spaced apart from each other, an assembling space being provided between the two guiding plates and the base board, each of the guiding plates having a long side, a short side and two assembling parts, the two assembling parts being spaced apart from each other, each of the assembling parts comprising a guiding groove and a first positioning groove, an extension direction of the guiding groove being parallel to the short side, the first positioning groove being in communication with the guiding groove and having an assembling direction, and the assembling direction being not perpendicular to the long side; and
an expansion device, having two side surfaces, the side surfaces having two guiding posts spaced apart from each other, and the guiding posts respectively entering the guiding grooves of the assembling parts along the extension direction and being fixed to the first positioning grooves of the assembling parts along the assembling direction, so that the expansion device is fixed in the assembling space.

2. The server chassis according to claim 1, wherein each of the guiding grooves comprises an opening part and a bottom part, the bottom part being adjacent to the base board, and the first positioning groove being located between the opening part and the base board.

3. The server chassis according to claim 2, wherein each of the assembling parts further comprises a second positioning groove, the first positioning groove being adjacent to the bottom part, and the second positioning groove being adjacent to the opening part.

4. The server chassis according to claim 3, wherein the first positioning groove and the second positioning groove of one of the two guiding plates are symmetrical with the first positioning groove and the second positioning groove of the other of the two guiding plates in position in the extension direction.

5. The server chassis according to claim 4, wherein each of the guiding plates has the first positioning groove and the second positioning groove on one side surface, and a third positioning groove and a fourth positioning groove on the other side surface, the third positioning groove being adjacent to the bottom part, and the fourth positioning groove being adjacent to the opening part, wherein the first positioning groove and the second positioning groove are offset from the third positioning groove and the fourth positioning groove in the extension direction.

6. The server chassis according to claim 1, wherein each of the guiding plates has the first positioning groove on one side surface and a third positioning groove on the other side surface, wherein the first positioning groove is offset from the third positioning groove in the extension direction.

7. The server chassis according to claim 1, wherein the chassis body further comprises a side plate connected to the base board, one of the guiding plates being fixed on the base board, and the other of the guiding plates being fixed on the side plate.

8. The server chassis according to claim 1, wherein a width of each of the guiding grooves is greater than twice a width of each of the guiding posts.

9. The server chassis according to claim 1, wherein each of the guiding plates has a limiting part, and the expansion device has a limiting member, when the guiding posts are respectively located in the first positioning grooves of the two guiding plates, the limiting member being matched with the limiting part.

10. The server chassis according to claim 1, wherein each of the guiding plates has a latch part, and the expansion device has a latching member (elastic fastener), when the guiding posts are respectively located in the first positioning grooves of the two guiding plates, the latching member being matched with the latch part.

11. A server, comprising:
a server chassis comprising:
a chassis body, comprising a base board;
two guiding plates, respectively fixed on the base board and spaced apart from each other, an assembling space being provided between the two guiding plates and the base board, each of the guiding plates having a long side, a short side and two assembling parts, the two assembling parts being spaced apart from each other, each of the assembling parts comprising a guiding groove and a first positioning groove, an extension direction of the guiding groove being parallel to the short side, the first positioning groove being in communication with the guiding groove and having an assembling direction, and the assembling direction being not perpendicular to the long side; and
an expansion device, having two side surfaces, the side surfaces having two guiding posts spaced apart from each other, and the guiding posts respectively entering the guiding grooves of the assembling parts along the extension direction and being fixed to the first positioning grooves of the assembling parts along the assembling direction, so that the expansion device is fixed in the assembling space, wherein the expansion device having an air inlet surface and an air outlet surface in the assembling direction, and the air inlet surface having a connecting part;
a motherboard, fixed on the base board of the server chassis and having a connector, the connecting part facing the motherboard; and
a connecting cable, having one end electrically connected to the connector and the other end connected to the connecting part.

12. The server according to claim 11, wherein the connecting cable has a first length, a distance between the air outlet surface and the connector is a second length, and a distance between the connecting part and the connector is a third length, wherein the second length is greater than the third length, and the first length is between the second length and the third length.

13. The server according to claim 11, wherein the expansion device has a heat dissipation space and an expansion circuit board, the heat dissipation space being respectively in communication with the air inlet surface, the air outlet surface and the chassis body, and the expansion circuit board being located in the heat dissipation space.
